(19) United States
(12) Patent Application Publication
(10) Pub. No.: US 2024/0113706 A1
(43) Pub. Date: Apr. 4, 2024

(54) SEMICONDUCTOR SWITCH

(71) Applicants: Kabushiki Kaisha Toshiba, Tokyo (JP); Toshiba Electronic Devices & Storage Corporation, Tokyo (JP)

(72) Inventor: Yukio TSUNETSUGU, Yokohama Kanagawa (JP)

(21) Appl. No.: 18/456,031

(22) Filed: Aug. 25, 2023

(30) Foreign Application Priority Data
Oct. 3, 2022 (JP) 2022-159750

(51) Int. Cl. H03K 17/082

(52) U.S. Cl. CPC H03K 17/0822; H03K 2017/0806

(57) ABSTRACT

According to the present embodiment, a semiconductor switch includes a switching transistor, a transmission element, a receiving element, and a power supply circuit. The switching transistor is connected between a pair of output terminals. An input signal is input to the transmission element. The receiving element is configured to generate a first current based on input of an input signal to the transmission element, wherein the receiving element is isolated from the transmission element. The power supply circuit is configured to supply a power supply current to a control electrode of the switching transistor in response to generation of the first current.

### CROSS-REFERENCE TO RELATED APPLICATIONS

This application is based upon and claims the benefit of priority from the prior Japanese Patent Application No. 2022-159750, filed on Oct. 3, 2022, the entire contents of which are incorporated herein by reference.

### FIELD

The embodiments of the present invention relate to a semiconductor switch.

### BACKGROUND

Conventionally, this kind of semiconductor switch includes a photovoltaic element that receives light from a light emitting element emitting light in response to an input signal and generates a photovoltage. The semiconductor switch also includes an output switching transistor that is made conductive by application of the photovoltage and charging of electric charges between the gate and the source. However, charging of the electric charges requires time.

### BRIEF DESCRIPTION OF THE DRAWINGS

FIG. 1 is a diagram illustrating a semiconductor integrated circuit example of a semiconductor switch according to a first embodiment;

FIG. 2 is a circuit diagram illustrating a configuration example of the semiconductor switch according to the first embodiment;

FIG. 3 is a diagram illustrating a semiconductor integrated circuit example of a semiconductor switch according to a second embodiment;

FIG. 4 is a circuit diagram illustrating a configuration example of the semiconductor switch according to the second embodiment;

FIG. 5 is a diagram illustrating a semiconductor integrated circuit example of a semiconductor switch according to a third embodiment;

FIG. 6 is a circuit diagram illustrating a configuration example of the semiconductor switch according to the third embodiment;

FIG. 7 is a schematic block diagram of the semiconductor switch according to a fourth embodiment;

FIG. 8A is a diagram schematically illustrating a circuit example of capacitive coupling;

FIG. 8B is a diagram schematically illustrating a circuit example of magnetic coupling;

FIG. 9 is another schematic block diagram of the semiconductor switch according to the fourth embodiment;

FIG. 10A is a diagram schematically illustrating a circuit example of capacitive coupling;

FIG. 108 is a diagram schematically illustrating a circuit example of magnetic coupling; and

FIG. 11 is still another schematic block diagram of the semiconductor switch according to the fourth embodiment.

### DETAILED DESCRIPTION

According to the present embodiment, a semiconductor switch includes a switching transistor, a transmission element, a receiving element, and a power supply circuit. The switching transistor is connected between a pair of output terminals. An input signal is input to the transmission element. The receiving element is configured to generate a first current based on input of an input signal to the transmission element, wherein the receiving element is isolated from the transmission element. The power supply circuit is configured to supply a power supply current to a control electrode of the switching transistor in response to generation of the first current.

Embodiments of the present invention are hereinafter explained with reference to the accompanying drawings. While characteristic configurations and operations of a semiconductor switch are mainly explained in the following embodiments, the semiconductor switch may include configurations and operations omitted in the following explanations.

### First Embodiment

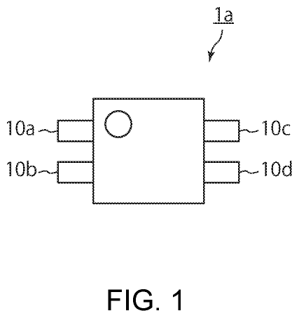

FIG. 1 is a schematic configuration diagram illustrating a semiconductor integrated circuit example of a semiconductor switch 1a according to a first embodiment. The semiconductor switch 1a according to the first embodiment is configured as a 4-pin semiconductor integrated circuit, for example. A terminal 10a is an anode (Anode2) terminal, a terminal 10b is a cathode (Cathode) terminal, a terminal 10c is a first output (O1) terminal, and a terminal 10d is a second output (O2) terminal.

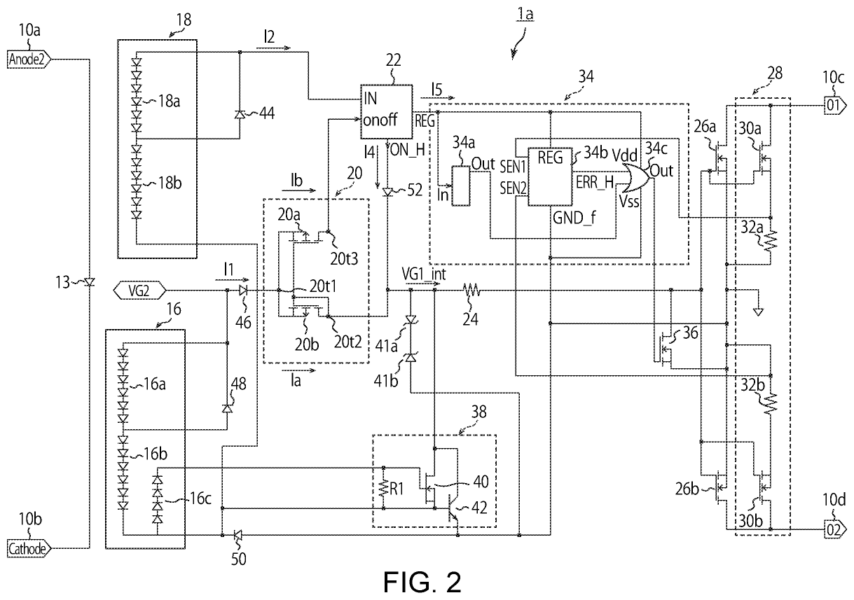

FIG. 2 is a circuit diagram illustrating a configuration example of the semiconductor switch 1a in the 4-pin semiconductor integrated circuit illustrated in FIG. 1. As illustrated in FIG. 2, the semiconductor switch 1a can make the terminals 10c and 10d conductive to each other in a shorter time. This semiconductor switch 1a includes a light emitting element 13, a first photodiode array 16, a second photodiode array 18, a current dividing circuit 20, a power supply circuit 22, a gate resistor 24, Nch switching transistors 26a and 26b, an overcurrent detection circuit 28, a protection circuit 34, an Nch switching transistor 36, a VG1_int discharge circuit 38, bidirectional Zener diodes 41a and 41b, and a plurality of diodes 44 to 52. The protection circuit 34 includes an overtemperature protection circuit 34a, an overcurrent protection circuit 34b, and an OR circuit 34c. The VG1_int discharge circuit 38 includes an Nch depletion switching transistor 40, a bipolar transistor 42, and a resistor R1.

The light emitting element 13 is a light emitting diode, for example. This light emitting element 13 emits an optical signal in response to an input signal input between the input terminal 10a and the input terminal 10b.

The first photodiode array 16 includes an 11th photodiode array 16a, a 12th photodiode array 16b, and a 13th photodiode array 16c. The first photodiode array 16 and the light emitting element 13 configure an isolation coupler of a PhotoMOS relay. The anode-side end of the 11th photodiode array 16a is connected to a terminal VG2 and the anode of a diode 46. The cathode of the diode 46 is connected to an input terminal 20t1 of the current dividing circuit 20.

The cathode-side end of the 11th photodiode array 16a is connected to the anode-side end of the 12th photodiode array 16b. The cathode-side end of the 12th photodiode array 16b is connected to the cathode of a diode 50, the base of the bipolar transistor 42, and one end of the resistor R1.

The first photodiode array 16 according to the present embodiment corresponds to a first photovoltaic element, the 11th photodiode array 16a corresponds to a first group of electromotive-force elements, the 12th photodiode array 16b corresponds to a second group of electromotive-force elements, and the 13th photodiode array 16c corresponds to a third group of electromotive-force elements.

The 11th photodiode array 16a includes a plurality of photodiodes connected in series, and receives an optical signal from the light emitting element 13 to generate a photovoltage. Similarly, the 12th photodiode array 16b includes a plurality of photodiodes connected in series, and receives an optical signal from the light emitting element 13 to generate a photovoltage. Similarly, the 13th photodiode array 16c includes a plurality of photodiodes connected in series, and receives an optical signal from the light emitting element 13 to generate a photovoltage. The photodiodes (PD) of the first photodiode array 16 and the second photodiode array 18 are, for example, photovoltaic photodiodes that use a pn junction of the semiconductor, and are used in a so-called solar cell mode.

The 11th photodiode array 16a and the 12th photodiode array 16b are connected to each other in series as described above. The cathode of a diode 48 is connected to the anode-side end of the 11th photodiode array 16a and the anode of the diode 46, and the anode of the diode 48 is connected to the cathode-side end of the 11th photodiode array 16a. More specifically, the anode of the diode 48 is connected to a connecting point between the cathode-side end of the 11th photodiode array 16a and the anode-side end of the 12th photodiode array 16b.

The cathode-side end of the 13th photodiode array 16c is connected to the gate of the Nch depletion switching transistor 40 of the VG1_int discharge circuit 38 and the other end of the resistor R1. The anode-side end of the 13th photodiode array 16c is connected to the cathode-side end of the 12th photodiode array 16b, the cathode of the diode 50, the base of the bipolar transistor 42, and the one end of the resistor R1. The anode of the diode 50 is connected to the emitter of the bipolar transistor 42, a ground terminal GND_f of the overcurrent protection circuit 34b of the protection circuit 34, and ground.

The anode-side end of the second photodiode array 18 is connected to an input terminal IN of the power supply circuit 22, and the cathode-side end is connected to ground.

The second photodiode array 18 includes a 21st photodiode array 18a and a 22nd photodiode array 18b. The second photodiode array 18 and the light emitting element 13 configure an isolation coupler of a PhotoMOS relay.

The 21st photodiode array 18a includes a plurality of photodiodes connected in series, and receives an optical signal from the light emitting element 13 to generate a photovoltage. Similarly, the 22nd photodiode array 18b includes a plurality of photodiodes connected in series, and receives the optical signal from the light emitting element 13 to generate a photovoltage.

The 21st photodiode array 18a and the 22nd photodiode array 18b are connected to each other in series. The anode of the diode 44 is connected to the cathode-side end of the 21st photodiode array 18a, and the cathode of the diode 44 is connected to the anode-side end of the 21st photodiode array 18a. The light emitting element 13 according to the present embodiment corresponds to a transmission element, the first photodiode array 16 according to the present embodiment corresponds to a first receiving element, and the second photodiode array 18 according to the present embodiment corresponds to a second receiving element.

The current dividing circuit 20 divides an input current I1 from the first photodiode array 16 to the input terminal 20t1 into a current 1a from a node 20t2 and a current Ib from a node 20t3. For example, the current dividing circuit 20 is a current mirror circuit. This current dividing circuit 20 includes a PMOSFET 20a and a PMOSFET 20b with the sources thereof connected to each other and the gates thereof connected to each other. Further, the gate and the drain of the PMOSFET 20b are connected to each other. The node 20t3 that is one of the outputs of the current dividing circuit 20 is connected to an onoff terminal of the power supply circuit 22, and the node 20t2 that is the other output of the current dividing circuit 20 is connected to one end of the gate resistor 24. The bidirectional Zener diodes 41a and 41b are connected to each other in series while being arranged in opposite directions to each other. More specifically, the anode of the Zener diode 41a is connected to the one end of the gate resistor 24, and the anode of the Zener diode 41b is connected ground. The cathodes of the Zener diodes 41a and 41b are connected to each other. That is, the bidirectional Zener diodes 41a and 41b clamp a voltage across the one end of the gate resistor 24 and the ground in a predetermined range.

The power supply circuit 22 is, for example, a photocoupler switching power supply, in which the node 20t3 of the current dividing circuit 20 is connected to the input terminal onoff and the anode-side end of the second photodiode array 18 is connected to the input terminal IN. An output terminal ON_H is connected to the anode of the diode 52 of which the cathode is connected to the one end of the gate resistor 24 in turn. The power supply circuit 22 thus outputs a power supply current I4 from the output terminal ON_H when the current Ib flows from the node 20t3 into the input terminal onoff. The power supply current I4 is added to the current Ia flowing from the node 20t2 of the current dividing circuit 20 to the one end of the gate resistor 24, so that a control current VG1_int rapidly increases.

Further, an output terminal REG is connected to an input terminal In of the overtemperature protection circuit 34a, an input terminal REG of the overcurrent protection circuit 34b, and a Vdd terminal of the OR circuit 34c. Accordingly, the power supply circuit 22 outputs a driving current I5 from the output terminal REG when the current Ib flows into the input terminal onoff.

The Nch switching transistors 26a and 26b are connected between a pair of output terminals 10c and 10d. The Nch switching transistors 26a and 26b are, for example, enhancement NMOSFETs, and the gates thereof are connected to the other end of the gate resistor 24. The drain of the Nch switching transistor 26a is connected to the terminal 10c, and the drain of the Nch switching transistor 26b is connected to the terminal 10d. The sources of the Nch switching transistors 26a and 26b are connected to each other. The connecting point between the sources of the Nch switching transistors 26a and 26b is connected to ground. The gate according to the present embodiment corresponds to a control electrode, the Nch switching transistor 26a corresponds to a first MOSFET, and the Nch switching transistor 26b corresponds to a second MOSFET.

The overcurrent detection circuit 28 includes Nch switching transistors 30a and 30b and detection resistors 32a and 32b. The Nch switching transistors 30a and 30b are, for example, enhancement NMOSFETs, and the gates thereof are connected to the other end of the gate resistor 24. The Nch switching transistor 30a according to the present embodiment corresponds to a third MOSFET, the detection resistor 32a corresponds to a first detection resistor, the detection resistor 32b corresponds to a second detection resistor, and the Nch switching transistor 30b corresponds to a fourth MOSFET.

The drain of the Nch switching transistor 30a is connected to the terminal 10c. The source of the Nch switching transistor 30a is connected to one end of the detection resistor 32a and an input terminal SEN1 of the overcurrent protection circuit 34b, and the other end of the detection resistor 32a is connected to ground.

The drain of the Nch switching transistor 30b is connected to the terminal 10d. The source of the Nch switching transistor 30b is connected to one end of the detection resistor 32b. The other end of the detection resistor 32b is connected to an input terminal SEN2 of the overcurrent protection circuit 34b and ground.

An output terminal Out of the overtemperature protection circuit 34a in the protection circuit 34 is connected to one input terminal of the OR circuit 34c. The overtemperature protection circuit 34a inverts an output signal from its output terminal Out from low (L) to high (H) when the temperature of the overtemperature protection circuit 34a becomes a set temperature or higher. The overtemperature protection circuit 34a includes, for example, a diode, compares a forward voltage of the diode with a reference voltage corresponding to the set temperature, and inverts the output signal from low (L) to high (H) when the temperature becomes the set temperature or higher.

An output terminal ERR_H of the overcurrent protection circuit 34b in the protection circuit 34 is connected to the other input terminal of the OR circuit 34c, and the terminal GND_f is connected to ground. The overcurrent protection circuit 34b includes a comparator that compares an input voltage V1 of the input terminal SEN1 and the reference voltage with each other and a comparator that compares an input voltage V2 of the input terminal SEN2 and the reference voltage with each other.

The overcurrent protection circuit 34b thus inverts an output signal from the output terminal ERR_H from low (L) to high (H) when the input voltage V1 or the input voltage V2 exceeds the reference voltage.

An output terminal Out of the OR circuit 34c is connected to the gate of the Nch switching transistor 36. A terminal Vss is connected to ground.

The Nch switching transistor 36 is, for example, an enhancement NMOSFET, in which the source is connected to ground, and the drain is connected to the gates of the Nch switching transistors 26a and 26b and the gates of the Nch switching transistors 30a and 30b. The Nch switching transistor 36 according to the present embodiment corresponds to a fifth MOSFET.

The Nch depletion switching transistor 40 in the VG1_int discharge circuit 38 is, for example, a depletion NMOSFET, and the bipolar transistor 42 is for example, an NPN bipolar transistor. The gate of the Nch depletion switching transistor 40 is connected to the cathode-side end of the 13th photodiode array 16c as described above, the source is connected to ground, and the drain is connected to one end of the gate resistor 24. The collector of the bipolar transistor 42 is connected to the one end of the gate resistor 24, the emitter is connected to ground, and the base is connected to the cathode of the diode 50.

The configuration of the semiconductor switch 1a according to the first embodiment has been described above. An operation example thereof is described below.

### (While Light Emitting Element 13 is Off)

Since the Nch depletion switching transistor 40 is a depletion NMOSFET, it is on (conductive) while the light emitting element 13 is off.

The potential of one end of the gate resistor 24 is applied to the base of the bipolar transistor 42, and the one end of the gate resistor 24 conducts through the bipolar transistor 42 to ground. Therefore, while the light emitting element 13 is off, the gate voltage of each of the Nch switching transistors 26a, 26b, 30a, and 30b becomes a predetermined low potential (a ground potential) equal to or lower than a threshold potential, so that electric charges in the Nch switching transistors 26a, 26b, 30a, and 30b are discharged, and the Nch switching transistors 26a, 26b, 30a, and 30b are off (non-conductive). Further, since the current flow into the input terminal onoff of the power supply circuit 22 is stopped, the power supply current I4 and the driving current I5 of the power supply circuit 22 are zero.

An operation of turning on the Nch switching transistors 26a, 26b, 30a, and 30b is described below.

### (Light Emission by Light Emitting Element 13)

The light emitting element 13 emits an optical signal in response to a first input signal input between the input terminal 10a and the input terminal 10b. In response to light emission by the light emitting element 13, the 11th photodiode array 16a, the 12th photodiode array 16b, and the 13th photodiode array 16c generate electromotive force. Similarly, the 21st photodiode array 18a and the 22nd photodiode array 18b generate electromotive force.

Accordingly, a reverse bias voltage is applied across the gate and the source of the Nch depletion switching transistor 40 by the electromotive force of the 13th photodiode array 16c, and the Nch depletion switching transistor 40 is turned off (made non-conductive). Further, the current I1 flows into the input terminal 20t1 of the current dividing circuit 20 from the first photodiode array 16 and is divided into the current Ia and the current Ib. This current Ib flows into the input terminal onoff of the power supply circuit 22 and turns on the power supply circuit 22 (makes it conductive).

In this case, the electromotive resistance of the 12th photodiode array 16b is reduced by the diode 48, and therefore the photovoltage increases at higher speed. Similarly, the electromotive resistance of the 22nd photodiode array 18b is reduced by the diode 44, and therefore the photovoltage increases at higher speed. Consequently, the control current VG1_int that is the total of the power supply current I4 caused by the current I2 on the second photodiode array 18 side and the current Ia increases rapidly and flows through the gate resistor 24. The control current VG1_int is then supplied to the gates of the Nch switching transistors 26a, 26b, 30a, and 30b via the gate resistor 24, so that the Nch switching transistors 26a, 26b, 30a, and 30b are charged at higher speed. As described above, based on the input signal input between the input terminal 10a and the input terminal 10b from outside, the first photodiode array 16 generates the current I1 with isolation from the input signal maintained, and the second photodiode array 18 generates the current I2 with isolation from the input signal maintained.

The sum of the electromotive force of the 11th photodiode array 16a and the electromotive force of the 12th photodiode array 16b gradually increases with time from light emission of the optical signal, and reaches a constant voltage. Similarly, the sum of the electromotive force of the 21st photodiode array 18a and the electromotive force of the 22nd photodiode array 18b gradually increases and reaches a constant voltage, and the control current VG1_int becomes a constant current.

As described above, the Nch switching transistors 26a, 26b, 30a, and 30b are charged at higher speed, and are turned on (made conductive) when the gate potential exceeds the threshold voltage. Further, the electromotive resistances are reduced in the first photodiode array 16 and the second photodiode array 18 by the diodes 44 and 48, respectively, and the control current VG1_int is increased in parallel at higher speed. Therefore, the Nch switching transistors 26a, 26b, 30a, and 30b can be turned on (made conductive) at further higher speed.

### (Startup of Protection Circuit 34)

When the power supply circuit 22 is turned on (made conductive) in response to the flow of the current Ib to the input terminal onoff, the driving current I5 flows, and the protection circuit 34 starts to be driven. While the Nch switching transistors 26a, 26b, 30a, and 30b are on, in a steady state where a normal drain current flows in each of the switching transistors 30a and 30b, the voltage across both ends of each of the detection resistors 32a and 32b drops below a reference potential of the comparator of the overcurrent protection circuit 34b, so that the output terminal ERR_H outputs a low-level signal.

Further, the overtemperature protection circuit 34a outputs a low-level signal from the output terminal Out in a steady state where a normal temperature is maintained. Thus, the output signal from the output terminal Out of the OR circuit 34c also maintains a low level, and therefore the Nch switching transistor 36 remains off (non-conductive).

### (Protection Against Overcurrent)

Protection against overcurrent is described below. When an overcurrent flows while the switching transistors 30a and 30b are on, both currents in positive and negative direction can flow in the switching transistors 30a and 30b. Regardless of the flowing direction of the overcurrent, a first voltage across both ends of the detection resistor 32a and a second voltage across both ends of the detection resistor 32b are output to the overcurrent protection circuit 34b. Thus, at least one of the first voltage across both ends of the resistor and the second voltage across both ends of the resistor becomes higher than the reference potential of the comparator of the overcurrent protection circuit 34b. Therefore, the overcurrent protection circuit 34b can convert the output signal output from the output terminal ERR_H from low to high regardless of the flowing direction of the overcurrent.

When the output signal from the output terminal ERR_H becomes high, the output signal from the output terminal Out of the OR circuit 34c also becomes high. Since the level of this high-level signal is set to be higher than the threshold voltage of the Nch switching transistor 36, the Nch switching transistor 36 is turned on.

When the Nch switching transistor 36 is turned on, the gate potential in the Nch switching transistors 26a, 26b, 30a, and 30b becomes a ground potential, that is, equal to or lower than the threshold potential, so that the Nch switching transistors 26a, 26b, 30a, and 30b are completely turned off. The drain current is thus cut off. Consequently, the current does not continue to flow to the Nch switching transistors 26a, 26b, 30a, and 30b to cause thermal destruction of the Nch switching transistors 26a, 26b, 30a, and 30b, for example, when a load short-circuit occurs between the terminals 10c and 10d. Accordingly, the Nch switching transistors 26a, 26b, 30a, and 30b can be prevented from being broken down.

### (Protection Against Overheating)

Protection against overheating is described below. When the overtemperature protection circuit 34a reaches a set temperature or higher while the light emitting element 13 is on, the output signal output from its output terminal Out is inverted from low (L) to high (H). When the output signal from the output terminal Out becomes high, the output signal from the output terminal Out of the OR circuit 34c also becomes high. Accordingly, the Nch switching transistor 36 is turned on by an operation equivalent to the above-described operation. When the Nch switching transistor 36 is turned on, the gate potential in the Nch switching transistors 26a, 26b, 30a, and 30b becomes a ground potential, and the Nch switching transistors 26a, 26b, 30a, and 30b are completely turned off, so that the drain current is cut off. Consequently, further overheating of the semiconductor switch 1a can be prevented, and the semiconductor switch 1a can be prevented from being damaged.

### (Turning Off)

As described above, when the light emitting element 13 is turned off, the Nch depletion switching transistor 40 is turned on (made conductive) with tf=1 to 2 ms.

As described above, the semiconductor switch 1a according to the present embodiment is configured in such a manner that the Nch switching transistors 26a and 26b are connected between a pair of output terminals 10c and 10d, and the power supply circuit 22 supplies the power supply current I4 to the gates of the Nch switching transistors 26a and 26b in accordance with the photovoltage generated when the first photodiode array 16 receives light from the light emitting element 13. Accordingly, a current in accordance with electromotive force of the second photodiode array 18 can be supplied to the gates of the Nch switching transistors 26a and 26b, in addition to a current generated by the first photodiode array 16. Consequently, the Nch switching transistors 26a and 26b can be made conductive at higher speed in response to light emission by the light emitting element 13.

### Second Embodiment

A semiconductor switch 1b according to a second embodiment is different from the semiconductor switch 1a according to the first embodiment in that the timing of generation of the photovoltage can be made different between the first photodiode array 16 and the second photodiode array 18. Differences of the semiconductor switch 1b from the semiconductor switch 1a according to the first embodiment are explained below.

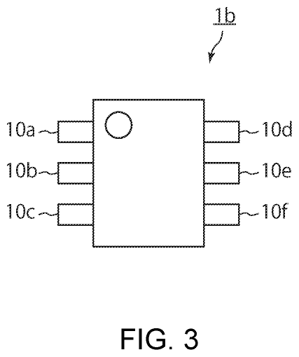

FIG. 3 is a schematic configuration diagram illustrating a semiconductor integrated circuit example of the semiconductor switch 1b according to the second embodiment. The semiconductor switch 1b according to the second embodiment is configured as a 6-pin semiconductor integrated circuit, for example. The terminal 10a is a first anode (Anode1) terminal, the terminal 10b is a second anode (Anode2) terminal, the terminal 10c is a cathode (Cathode) terminal, the terminal 10d is a first output (O1) terminal, a terminal 10e is a non-connection (NC) terminal, and a terminal 10f is a second output (O2) terminal.

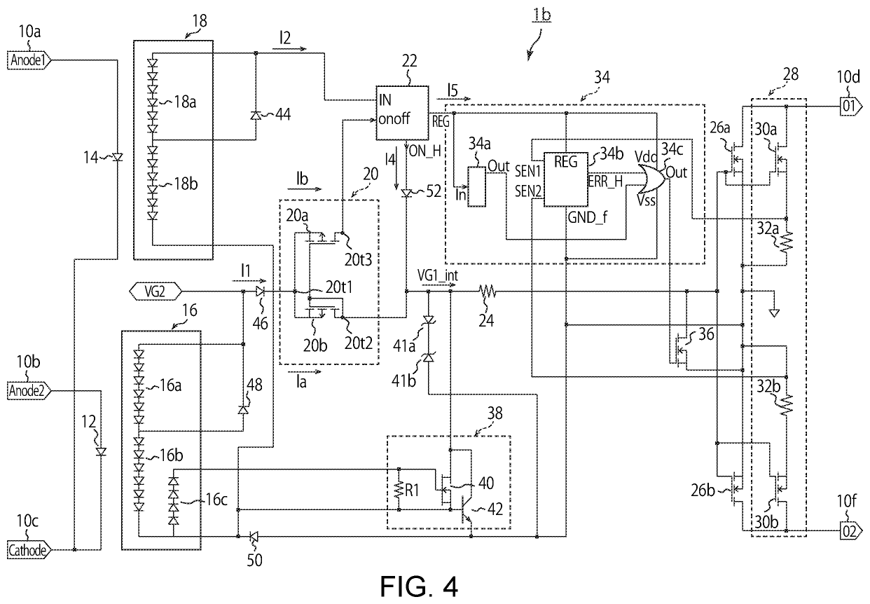

FIG. 4 is a circuit diagram illustrating a configuration example of the semiconductor switch 1b in the 6-pin semiconductor integrated circuit illustrated in FIG. 3. This semiconductor switch 1b is different from the semiconductor switch 1a according to the first embodiment in including a first light emitting element 12 and a second light emitting element 14.

The first light emitting element 12 is, for example, a light emitting diode and emits a first optical signal in response to a first input signal input between the input terminal 10b (Anode2) and the input terminal 10c (Cathode).

The second light emitting element 14 is, for example, a light emitting diode and emits a second optical signal in response to a second input signal input between the input terminal 10a (Anode1) and the input terminal 10c (Cathode).

An operation example of the semiconductor switch 1b according to the second embodiment is described below.

### (While First Light Emitting Element 12 is Off)

Since the Nch depletion switching transistor 40 is a depletion NMOSFET, it is on (conductive) while the first light emitting element 12 is off. The Nch depletion switching transistor 40 thus connects one end of the gate resistor 24 to ground. Therefore, while the first light emitting element 12 is off, the gate voltage of the Nch switching transistors 26a, 26b, 30a, and 30b becomes a predetermined low potential (a ground potential) equal to or lower than a threshold potential, so that electric charges in the Nch switching transistors 26a, 26b, 30a, and 30b are discharged, and the Nch switching transistors 26a, 26b, 30a, and 30b are off (non-conductive). Further, since the current flow into the input terminal onoff of the power supply circuit 22 is stopped, the power supply current I4 and the driving current I5 of the power supply circuit 22 are zero.

An operation of turning on the Nch switching transistors 26a, 26b, 30a, and 30b is described below.

### (Light Emission by Second Light Emitting Element 14)

The second light emitting element 14 emits the second optical signal in response to the second input signal input between the input terminal 10a (Anode1) and the input terminal 10c (Cathode). Thus, the 21st photodiode array 18a and the 22nd photodiode array 18b generate electromotive force. In this case, the electromotive resistance of the 22nd photodiode array 18b is reduced by the diode 44, and therefore the photovoltage increases at higher speed. The sum of the electromotive force of the 21st photodiode array 18a and the electromotive force of the 22nd photodiode array 18b gradually increases with time from light emission of the second optical signal, and reaches a constant voltage. The photovoltage by the 21st photodiode array 18a and the 22nd photodiode array 18b is applied to the input terminal IN of the power supply circuit 22.

### (Light Emission by First Light Emitting Element 12)

Subsequently, after the sum of the electromotive force of the 21st photodiode array 18a and the electromotive force of the 22nd photodiode array 18b reaches the constant voltage, the first input signal is input between the input terminal 10b (Anode2) and the input terminal 10c (Cathode). The first light emitting element 12 emits the first optical signal in response to this first input signal. The 11th photodiode array 16a, the 12th photodiode array 16b, and the 13th photodiode array 16c thus generate electromotive force.

Accordingly, a reverse bias voltage is applied across the gate and the source of the Nch depletion switching transistor 40 by the electromotive force of the 13th photodiode array 16c, and the Nch depletion switching transistor 40 is turned off (made non-conductive). Further, the current I1 flows into the input terminal 20t1 of the current dividing circuit 20 from the first photodiode array 16 and is divided into the current Ia and the current Ib. This current Ib flows into the input terminal onoff of the power supply circuit 22 and turns on the power supply circuit 22 (makes it conductive). Consequently, the control current VG1_int that is the total of the power supply current I4 caused by the current I2 on the second photodiode array 18 side, the second photodiode array 18 having reached the constant voltage, and the current Ia flows to the gate resistor 24. In this case, since the second photodiode array 18 has reached the constant potential, the power supply current I4 has reached a constant current at the same time as the start of supply.

Consequently, the control current VG1_int including the power supply current I4 that has become constant is supplied to the gates of the Nch switching transistors 26a, 26b, 30a, and 30b, so that the Nch switching transistors 26a, 26b, 30a, and 30b start to be charged.

At this time, on the first photodiode array 16 side, the sum of the electromotive force of the 11th photodiode array 16a and the electromotive force of the 12th photodiode array 16b gradually increases with time from light emission of the second optical signal, and the current Ia also gradually increases. Accordingly, as for the control current VG1_int, the current Ia supplied from the first photodiode array 16 side also increases rapidly in addition to the power supply current I4 that has become constant. Therefore, the Nch switching transistors 26a, 26b, 30a, and 30b are charged at higher speed. When the gates of the Nch switching transistors 26a, 26b, 30a, and 30b are charged and the gate potential exceeds the threshold voltage, the Nch switching transistors 26a, 26b, 30a, and 30b are turned on (become conductive). In this case, since the electromotive resistance of the 12th photodiode array 16b is reduced by the diode 48, the electromotive force increases at higher speed, and the Nch switching transistors 26a, 26b, 30a, and 30b are charged at further higher speed. Then, the sum of the electromotive force of the 11th photodiode array 16a and the electromotive force of the 12th photodiode array 16b becomes a constant voltage as time passes, so that the control current VG1_int becomes a constant current.

As described above, the second light emitting element 14 is turned on earlier than the first light emitting element 12, and electricity is generated on the second photodiode array 18 side to a constant voltage in advance. Therefore, the power supply circuit 22 can output the power supply current I4 that has reached a constant current. Accordingly, the control current VG1_int including the power supply current I4 that has become constant is supplied to the gates of the Nch switching transistors 26a, 26b, 30a, and 30b, and therefore the Nch switching transistors 26a, 26b, 30a, and 30b can be charged at further higher speed. As described above, since the second light emitting element 14 is turned on earlier than the first light emitting element 12, and electricity is generated on the second photodiode array 18 side to a constant voltage in advance, the Nch switching transistors 26a, 26b, 30a, and 30b can be turned on (made conductive) at further higher speed than in the semiconductor switch 1a according to the first embodiment.

As described above, the semiconductor switch 1b according to the present embodiment is configured in such a manner that the Nch switching transistors 26a and 26b are connected between a pair of output terminals 10d and 10f, and the power supply circuit 22 supplies the power supply current I4 that is equal to or more than a predetermined value to the gates of the Nch switching transistors 26a and 26b in accordance with the photovoltage generated when the first photodiode array 16 receives light from the first light emitting element 12. Consequently, the Nch switching transistors 26a and 26b can be made conductive at higher speed in response to light emission by the first light emitting element 12.

### Third Embodiment

A semiconductor switch 1c according to a third embodiment is different from the semiconductor switch 1b according to the second embodiment in that a VBB power supply is connected to the input terminal IN of the power supply circuit 22. Differences of the semiconductor switch 1c from the semiconductor switch 1b according to the second embodiment are explained below.

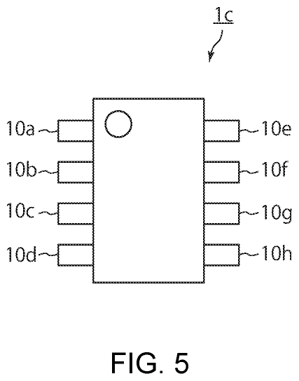

FIG. 5 is a schematic configuration diagram illustrating a semiconductor integrated circuit example of the semiconductor switch 1c according to the third embodiment. The semiconductor switch 1c is configured as an 8-pin semiconductor integrated circuit, for example. The terminal 10b is an anode (Anode2) terminal, the terminals 10a and 10d are non-connection (NC) terminals, the terminal 10c is a cathode (Cathode) terminal, the terminal 10e is an output 1 (O1) terminal, the terminal 10f is a VBB terminal, a terminal 10g is a ground (2_GND) terminal, and a terminal 10h is an output 2 (O2) terminal.

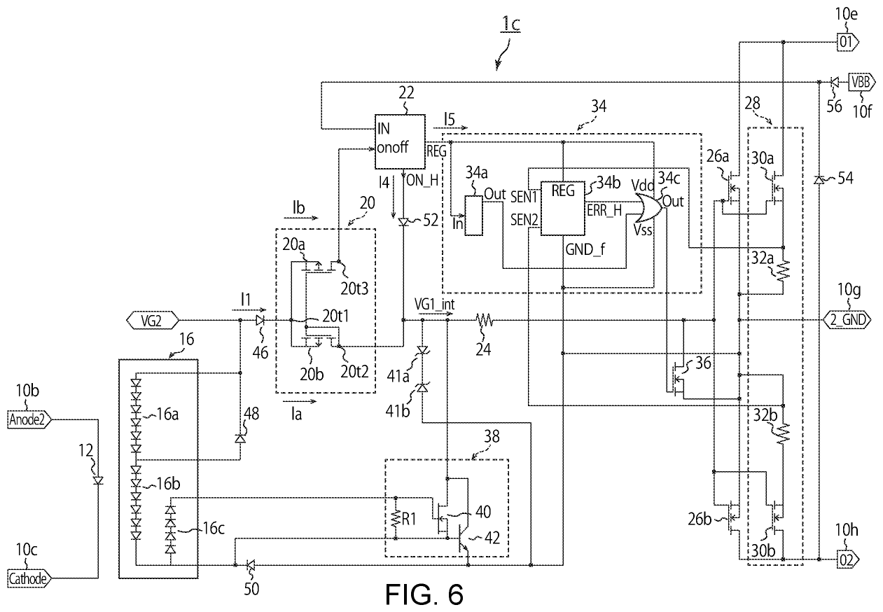

FIG. 6 is a circuit diagram illustrating a configuration example of the semiconductor switch 1c in the 8-pin semiconductor integrated circuit illustrated in FIG. 5. As illustrated in FIG. 6, the semiconductor switch 1c according to the third embodiment is different from the semiconductor switch 1b according to the second embodiment in that a VBB power supply is connected to the input terminal IN of the power supply circuit 22 via a blocking diode 56, and only the first photodiode array 16 and the first light emitting element 12 are provided without providing the second photodiode array and the second light emitting element.

Further, the anode of a blocking diode 54 is connected to the terminal 10h, and the cathode is connected to the cathode of the blocking diode 56 and the input terminal IN of the power supply circuit 22. Furthermore, the anode of the blocking diode 56 is connected to the VBB terminal 10f, and the cathode is connected to the input terminal IN of the power supply circuit 22. The blocking diodes 54 and 56 operate in such a manner that the potential at the terminal 10f becomes higher than the potential at the terminal 10h when the potential at the terminal 10e is higher than the potential at the terminal 10h. Further, they operate in such a manner that the potential at the terminal 10f becomes lower than the potential at the terminal 10h when the potential at the terminal 10e is lower than the potential at the terminal 10h.

As described above, in the semiconductor switch 1c according to the third embodiment, only one light emitting element 12 is provided. Therefore, tuning on of the first photodiode array 16 and start of voltage supply from the VBB power supply are performed simultaneously, and turning off of the light emitting element 12 and stop of voltage supply from the VBB power supply are performed simultaneously. Further, the power supply circuit 22 starts supply of the power supply current I4 in accordance with the voltage from the VBB power supply in response to light emission by the first light emitting element 12. In this case, as for the power supply circuit 22, the power supply current I4 has reached a constant current at the time of start of supply, because the VBB power supply is at a constant potential. Accordingly, the power supply circuit 22 can supply the power supply current I4 that has reached a predetermined value to the gates of the Nch switching transistors 26a and 26b in accordance with the photovoltage generated when the first photodiode array 16 receives light from the first light emitting element 12.

In addition, the amount of the power supply current I4 can be adjusted in accordance with the potential at the VBB power supply. For example, the potential at the VBB power supply can be set to such a level that the Nch switching transistors 26a, 26b, 30a, and 30b can be turned on (made conductive) at approximately the same time as the timing at which the power supply circuit 22 is turned on.

With this configuration, in the semiconductor switch 1c according to the third embodiment, the Nch switching transistors 26a, 26b, 30a, and 30b can be turned on (made conductive) at approximately the same time as the timing at which the power supply circuit 22 is turned on. Therefore, the time required for turning on the Nch switching transistors 26a, 26b, 30a, and 30b (making them conductive) depends on the response time of the power supply circuit 22. For example, the Nch switching transistors 26a, 26b, 30a, and 30b can be turned on (made conductive) in 20 msec. As described above, the power supply current I4 that has reached a constant current at the same time as generation of photovoltage by the first photodiode array 16 because of voltage supply from the VBB power supply can be supplied to the gates of the Nch switching transistors 26a, 26b, 30a, and 30b. Thus, depending on a voltage set value in the VBB power supply, the Nch switching transistors 26a, 26b, 30a, and 30b can be turned on (made conductive) at further higher speed than in the semiconductor switch 1b according to the second embodiment.

As described above, in the semiconductor switch 1c according to the present embodiment, a VBB power supply is connected to the input terminal IN of the power supply circuit 22. Accordingly, the power supply circuit 22 can supply the power supply current I4 that has reached a predetermined value to the gates of the Nch switching transistors 26a and 26b in accordance with the photovoltage generated when the first photodiode array 16 receives light from the first light emitting element 12.

In addition, the amount of the power supply current I4 can be adjusted by adjusting the potential at the VBB power supply. Thus, depending on the potential at the VBB power supply, the Nch switching transistors 26a, 26b, 30a, and 30b can be turned on at approximately the same time as the timing at which the power supply circuit 22 is turned on.

### Fourth Embodiment

The semiconductor switches according to the first to third embodiments have been described as including the light emitting elements 12, 13, and 14 as examples of a transmission element and the photodiode arrays 16 and 18 as examples of a receiving element that generates a current. The transmission elements and the receiving elements have been described as an example of an isolation coupler. However, the isolation coupler can be configured not only by an insulator such as an optical coupling device that transmits and receives an optical signal but also by an insulator that transmits energy in a contactless manner by, for example, capacitive coupling or magnetic coupling.

For example, in a case of transmitting energy by capacitive coupling, a capacitor may be provided between a transmission element and a receiving element, one electrode of this capacitor may be arranged on the transmission element, and the other electrode may be arranged on the receiving element.

In a case of transmitting energy by magnetic coupling, a transmission-element side coil and a receiving-element side coil may be arranged to be coupled by magnetic coupling, for example.

Also in the insulator that transmits energy by magnetic coupling or capacitive coupling, the receiving-element side generates a current based on an input signal to the transmission-element side. In accordance with this current, the power supply circuit 22 supplies a power supply current to the gates of the Nch switching transistors 26a and 26b. The Nch switching transistors 26a and 26b can thus be made conductive at high speed. Although the present embodiment is described by way of an example of an insulator using capacitive coupling or magnetic coupling, the configuration of the insulator is not limited thereto. For example, a coil may be provided on the transmission-element side, and a resistor bridge circuit or a magnetoresistive element may be provided on the receiving-element side. As described above, the semiconductor switch according to the present embodiment has a configuration in which a semiconductor element on the transmission-element side and a semiconductor element on the receiving-element side are isolated from each other by galvanic isolation, as in the semiconductor switches according to the first to third embodiments described above.

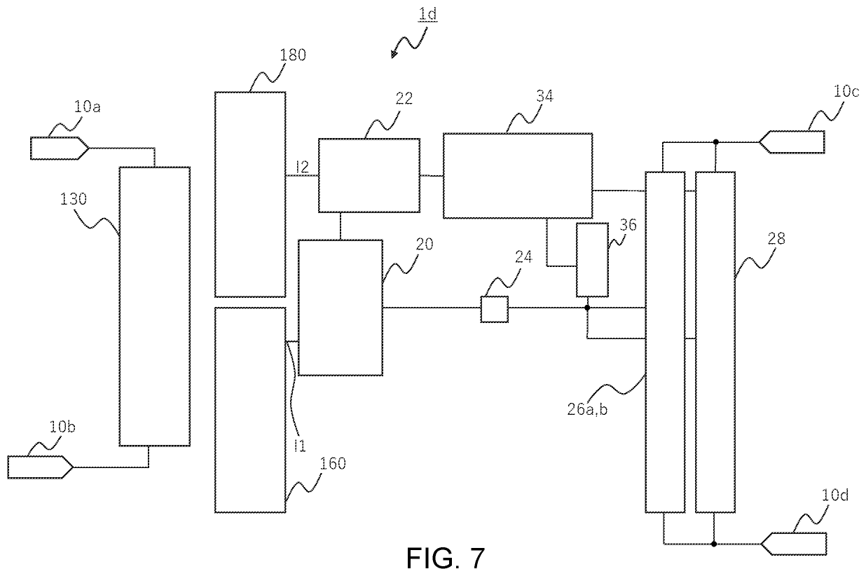

FIG. 7 is a schematic block diagram of a semiconductor switch 1d according to a fourth embodiment. The semiconductor switch 1d according to the fourth embodiment has a configuration equivalent to that of the semiconductor switch 1a according to the first embodiment described above except for an isolation coupler. In FIG. 7, constituent elements identical to those of the semiconductor switch 1a according to the first embodiment described above are denoted by like reference signs and detailed explanations thereof are omitted.

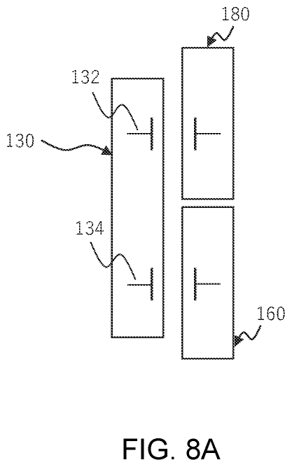

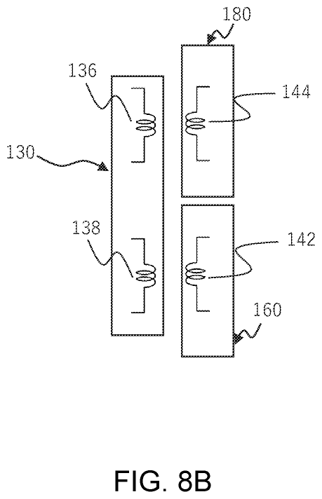

As illustrated in FIG. 7, the semiconductor switch 1d according to the present embodiment is different from the semiconductor switch 1a according to the first embodiment in including a transmission element 130, a first receiving element 160, and a second receiving element 180 in place of the light emitting element 13 and the photodiode arrays 16 and 18. Here, a circuit example of the transmission element 130, the first receiving element 160, and the second receiving element 180 is described with reference to FIGS. 8A and 8B.

FIG. 8A is a diagram schematically illustrating a circuit example of capacitive coupling in the transmission element 130, the first receiving element 160, and the second receiving element 180 illustrated in FIG. 7. As illustrated in FIG. 8A, the transmission element 130 includes a first terminal of a capacitor 132 and a first terminal of a capacitor 134. The first receiving element 160 includes a second terminal of the capacitor 134. Similarly, the second receiving element 180 includes a second terminal of the capacitor 132.

The capacitors 132 and 134 accumulate electric charges based on an input signal between the terminals 10a and 10b (see FIG. 7) and discharge the accumulated electric charges. An alternating current is generated based on the discharged electric charges. A rectifier (not illustrated) converts the alternating current generated in the capacitor 132 to the input current I2 that is a smoothed direct current (see FIG. 7). At the same time, the rectifier (not illustrated) converts the alternating current generated in the capacitor 134 to the current I1 that is a smoothed direct current (see FIG. 7). The input current I1 flows to the current dividing circuit 20, and the current I2 flows to the power supply circuit 22. Thereafter, the semiconductor switch 1d according to the present embodiment performs an operation equivalent to that of the semiconductor switch 1a according to the first embodiment.

FIG. 8B is a diagram schematically illustrating a circuit example of magnetic coupling in the transmission element 130, the first receiving element 160, and the second receiving element 180 illustrated in FIG. 7. As illustrated in FIG. 8B, the transmission element 130 includes coils 136 and 138. The first receiving element 160 includes a coil 142, and the second receiving element 180 includes a coil 144.

The coil 138 causes a potential difference to be generated between both ends of the coil 142 based on an input signal between the terminals 10a and 10b (see FIG. 7). A rectifier (not illustrated) thus converts an alternating current generated in accordance with the potential difference across the coil 142 to the input current I1 that is a smoothed direct current (see FIG. 7). At the same time, the rectifier (not illustrated) converts an alternating current generated in accordance with the potential difference across the coil 144 to the current I2 that is a smoothed direct current (see FIG. 7). The input current I1 flows to the current dividing circuit 20, and the current I2 flows to the power supply circuit 22. Thereafter, the semiconductor switch 1d according to the present embodiment performs an operation equivalent to that of the semiconductor switch 1a according to the first embodiment.

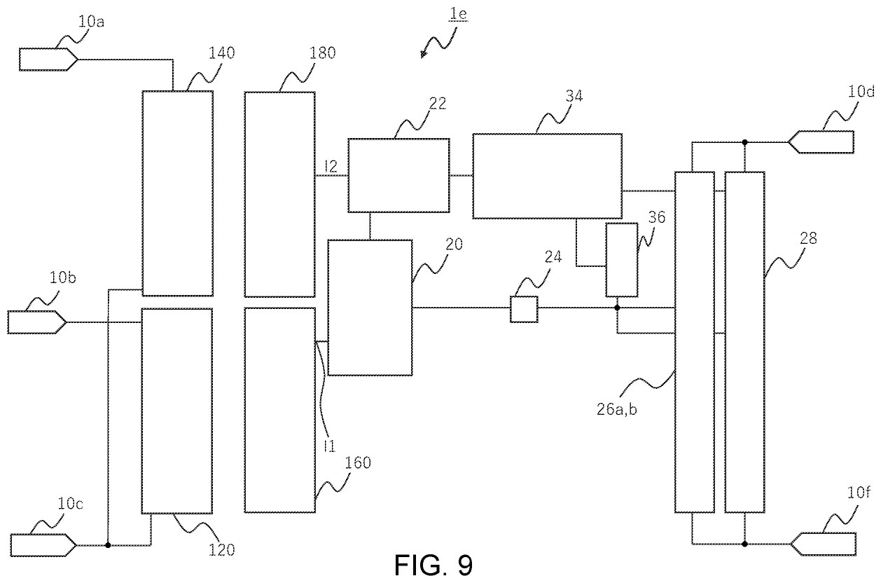

FIG. 9 is another schematic block diagram illustrating a configuration example obtained by replacing optical coupling in the semiconductor switch according to the second embodiment with capacitive coupling or magnetic coupling. The semiconductor switch 1e according to the fourth embodiment has an identical configuration as that of the semiconductor switch 1b according to the second embodiment described above except for the configuration of the isolation coupler. In FIG. 9, constituent elements identical to those of the semiconductor switch 1b according to the second embodiment described above are denoted by like reference signs and detailed explanations thereof are omitted.

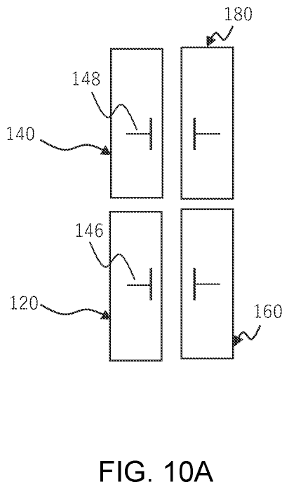

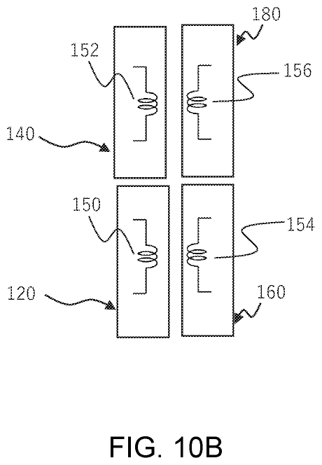

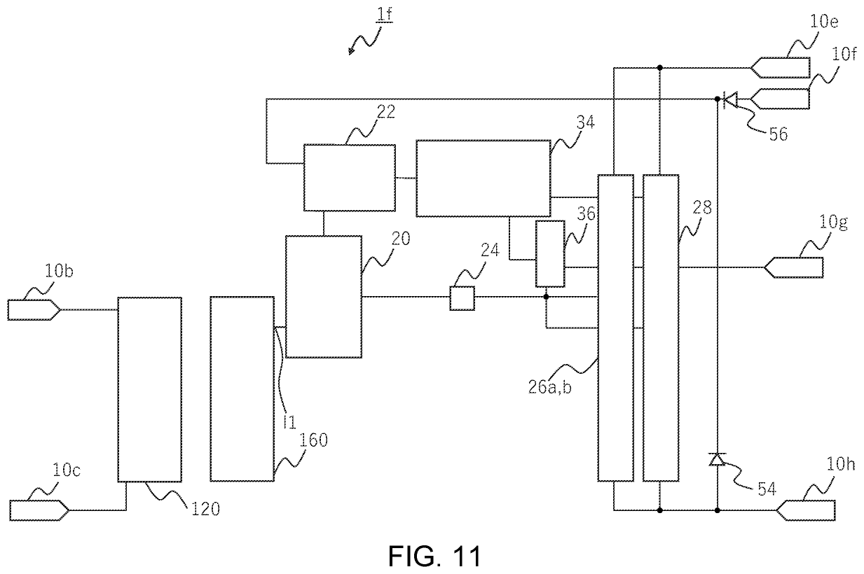

As illustrated in FIG. 9, the semiconductor switch 1e according to the present embodiment is different from the semiconductor switch 1b according to the second embodiment in including a first transmission element 120, a second transmission element 140, the first receiving element 160, and the second receiving element 180 in place of the light emitting elements 12 and 14 and the photodiode arrays 16 and 18. Here, a circuit example of the first transmission element 120, the second transmission element 140, the first receiving element 160, and the second receiving element 180 is described with reference to FIGS. 10A and 10B.

FIG. 10A is a diagram schematically illustrating a circuit example of capacitive coupling in the first transmission element 120, the second transmission element 140, the first receiving element 160, and the second receiving element 180 illustrated in FIG. 9. As illustrated in FIG. 10A, the first transmission element 120 includes a first terminal of a capacitor 146, and the second transmission element 140 includes a first terminal of a capacitor 148. The first receiving element 160 includes a second terminal of the capacitor 146, and the second receiving element 180 includes a second terminal of the capacitor 148.

The capacitor 148 accumulates electric charges based on an input signal between the terminals 10a and 10c (see FIG. 9) and discharges the accumulated electric charges. An alternating current is generated based on the discharged electric charges. A rectifier (not illustrated) converts the alternating current generated in the capacitor 148 to the input current I2 that is a smoothed direct current (see FIG. 9). The current I2 flows to the power supply circuit 22.

After the input current I2 has reached a constant current, the capacitor 146 accumulates electric charges based on an input signal between the terminals 10b and 10c (see FIG. 9) and discharges the accumulated electric charges. An alternating current is generated based on the discharged electric charges. The rectifier (not illustrated) converts the alternating current generated in the capacitor 146 to the current I1 that is a smoothed direct current (see FIG. 9). The input current I1 flows to the current dividing circuit 20. Thereafter, the semiconductor switch 1d according to the present embodiment performs an operation equivalent to that of the semiconductor switch 1b according to the second embodiment.

FIG. 10B is a diagram schematically illustrating a circuit example of magnetic coupling in the first transmission element 120, the second transmission element 140, the first receiving element 160, and the second receiving element 180 illustrated in FIG. 9. As illustrated in FIG. 10B, the first transmission element 120 includes a coil 150, and the second transmission element 140 includes a coil 152. The first receiving element 160 includes a coil 154, and the second receiving element 180 includes a coil 156.

The coil 152 causes a potential difference to be generated between both ends of the coil 156 based on an input signal between the terminals 10a and 10c (see FIG. 9). A rectifier (not illustrated) thus converts an alternating current generated in accordance with the potential difference across the coil 156 to the input current I2 that is a smoothed direct current (see FIG. 9). After the input current I2 has reached a constant current, the coil 150 causes a potential difference to be generated between both ends of the coil 154 based on an input signal between the terminals 10b and 10c (see FIG. 9). The rectifier (not illustrated) converts an alternating current generated in accordance with the potential difference across the coil 154 to the current I1 that is a smoothed direct current (see FIG. 9). The current I2 flows to the power supply circuit 22, and the current I1 flows to the current dividing circuit 20. Thereafter, the semiconductor switch 1e according to the present embodiment performs an operation equivalent to that of the semiconductor switch 1b according to the second embodiment.

FIG. 11 is another schematic block diagram illustrating a configuration example obtained by replacing optical coupling in the semiconductor switch according to the third embodiment with capacitive coupling or magnetic coupling. The semiconductor switch 1f according to the fourth embodiment has an identical configuration as that of the semiconductor switch 1c according to the third embodiment described above except for the configuration of the isolation coupler. In FIG. 11, constituent elements identical to those of the semiconductor switch 1c according to the third embodiment described above are denoted by like reference signs and detailed explanations thereof are omitted.

As illustrated in FIG. 11, the semiconductor switch 1f according to the present embodiment is different from the semiconductor switch 1c according to the third embodiment in including the first transmission element 120 and the first receiving element 160 in place of the light emitting element 12 and the photodiode array 16. Here, a circuit example of the first transmission element 120 and the first receiving element 160 is described with reference to FIGS. 10A and 10B.

The semiconductor switch 1f according to the present embodiment can include a configuration equivalent to that of the first transmission element 120 and the first receiving element 160 illustrated in FIG. 10A.

The capacitor 146 accumulates electric charges based on an input signal between the terminals 10b and 10c (see FIG. 11) and discharges the accumulated electric charges. An alternating current is generated based on the discharged electric charges. A rectifier (not illustrated) converts the alternating current generated in the capacitor 146 to the current I1 that is a smoothed direct current (see FIG. 11). The current I1 flows to the current dividing circuit 20. Thereafter, the semiconductor switch 1f according to the present embodiment performs an operation equivalent to that of the semiconductor switch 1c according to the third embodiment.

Further, the semiconductor switch 1f according to the present embodiment can include a configuration equivalent to that of the first transmission element 120 and the first receiving element 160 illustrated in FIG. 10B. The coil 150 causes a potential difference to be generated between both ends of the coil 154 based on an input signal between the terminals 10b and 10c (see FIG. 11). A rectifier (not illustrated) thus converts an alternating current generated in accordance with the potential difference across the coil 154 to the current I1 that is a smoothed direct current (see FIG. 11). The current I1 flows to the current dividing circuit 20. Thereafter, the semiconductor switch if according to the present embodiment performs an operation equivalent to that of the semiconductor switch 1c according to the third embodiment.

As described above, the semiconductor switches 1d, 1e, and if according to the present embodiment can generate the current I1, I2, or the like based on an input signal from outside with isolation maintained, by using capacitive coupling or magnetic coupling in place of optical coupling.

While certain embodiments of the present invention have been described, these embodiments have been presented by way of example only, and are not intended to limit the scope of the inventions. Indeed, the novel embodiments described herein may be embodied in a variety of other forms and various omissions, substitutions, and changes may be made without departing from the spirit of the inventions. Such embodiments and modifications thereof are included in the spirit and scope of the invention and are also included in the scope of the inventions described in the claims and equivalents thereof.

1. A semiconductor switch comprising:
a switching transistor connected between a pair of output terminals;
a transmission element to which an input signal is input;
a receiving element configured to generate a first current based on input of the input signal to the transmission element, wherein the receiving element is isolated from the transmission element; and
a power supply circuit configured to supply a power supply current to a control electrode of the switching transistor in response to generation of the first current.

2. The switch of claim 1, wherein
the transmission element is a first light emitting element configured to emit light based on input of the input signal,
the receiving element has at least a first photovoltaic element configured to generate a photovoltage when receiving light,
the switch further includes a second photovoltaic element configured to generate a photovoltage when receiving light, and
the power supply circuit outputs the power supply current that has reached a predetermined current in accordance with a current supplied from the second photovoltaic element.

3. The switch of claim 2, further comprising a second light emitting element, wherein
the second photovoltaic element is configured to generate the photovoltage when receiving light from the second light emitting element, and
the second light emitting element is turned on earlier than the first light emitting element.

4. The switch of claim 3, wherein
the switching transistor includes a first MOSFET and a second MOSFET connected to each other in series between the pair of output terminals, same one type terminals of the first MOSFET and the second MOSFET being coupled to each other,
the control electrode comprises a gate of the first MOSFET and a gate of the second MOSFET connected to each other, and
the first MOSFET and the second MOSFET are charged by the power supply current in addition to a current generated by the first photovoltaic element, and are made conductive.

5. The switch of claim 4, further comprising a current dividing circuit connected to a positive-electrode side end of the first photovoltaic element, wherein
one of output nodes of the current dividing circuit is connected to the power supply circuit,
the other output node of the current dividing circuit is connected to the control electrode, and
the power supply circuit is configured to output the power supply current in accordance with a current supplied from the one output node of the current dividing circuit.

6. The switch of claim 5, further comprising:
a current detection circuit capable of detecting an overcurrent flowing in both directions between the pair of output terminals; and
a protection circuit configured to provide the gates of the first MOSFET and the second MOSFET with a predetermined low potential in accordance with an output value of the current detection circuit and make the first MOSFET and the second MOSFET non-conductive.

7. The switch of claim 6, wherein the protection circuit is driven by a driving current supplied from the power supply circuit.

8. The switch of claim 6, wherein
the current detection circuit includes a third MOSFET, a first detection resistor, a second detection resistor, and a fourth MOSFET connected in series,
a drain of the third MOSFET is connected to one of the output terminals, a source of the third MOSFET is connected to one end of the first detection resistor, the other end of the first detection resistor is connected to one end of the second detection resistor, the other end of the second detection resistor is connected to a source of the fourth MOSFET, and a drain of the fourth MOSFET is connected to the other of the output terminals,
the power supply circuit supplies the power supply current to a gate of the third MOSFET and a gate of the fourth MOSFET in accordance with the current supplied from the one output node of the current dividing circuit,
a first voltage across both ends of the first detection resistor and a second voltage across both ends of the second detection resistor are supplied to the protection circuit as the output value, and
the protection circuit provides the gates of the first MOSFET, the second MOSFET, the third MOSFET, and the fourth MOSFET with the predetermined low potential when at least one of the first voltage across both ends and the second voltage across both ends exceeds a set voltage.

9. The switch of claim 8, wherein the protection circuit further includes an overtemperature protection circuit configured to output an output signal indicating that a temperature has exceeded a predetermined set temperature, and
the protection circuit is configured to provide the gates of the first MOSFET and the second MOSFET with the predetermined low potential in accordance with the output signal.

10. The switch of claim 1, wherein the power supply circuit is configured to supply a power supply current supplied from a constant voltage source to the control electrode.

11. The switch of claim 10, wherein
the switching transistor includes a first MOSFET and a second MOSFET connected to each other in series between the pair of output terminals, same one type terminals of the first MOSFET and the second MOSFET being coupled to each other,
the control electrode comprises a gate of the first MOSFET and a gate of the second MOSFET being coupled to each other, and
the first MOSFET and the second MOSFET are charged by the power supply current supplied from the constant voltage source in addition to a current generated by the receiving element, and are made conductive.

12. The switch of claim 1, wherein the receiving element is configured to generate the first current by at least any of optical coupling, magnetic coupling, and capacitive coupling with the transmission element.

13. The switch of claim 4, wherein
the sources of the first MOSFET and the second MOSFET are connected to each other.

14. The switch of claim 11, wherein
the sources of the first MOSFET and the second MOSFET are connected to each other.
